(19) United States
(12) Patent Application Publication
(10) Pub. No.: US 2019/0094270 A1
(43) Pub. Date: Mar. 28, 2019

(54) SYSTEM AND COMPUTER-IMPLEMENTED METHOD FOR DETERMINING LOAD SHAPES FOR DISTRIBUTED GENERATION CUSTOMERS

(71) Applicant: Black & Veatch Holding Company, Overland Park, KS (US)

(72) Inventors: Howard Edwin Overcast, McDonough, GA (US); David Feron DesLauriers, Westborough, MA (US); Alok Ashok Patil, New York, NY (US)

(73) Assignee: Black & Veatch Holding Company, Overland Park, KS (US)

(21) Appl. No.: 15/718,194

(22) Filed: Sep. 28, 2017

(51) Int. Cl. G01R 11/56; G01D 4/02; G06Q 30/04; G06Q 50/06; H02J 3/00

(52) U.S. Cl. CPC G01R 11/56; G01D 4/02; H02J 3/008; G06Q 50/06; G06Q 30/04

(57) ABSTRACT

A system and computer-implemented method for determining load shapes for distributed generation (DG) customers in an electricity generation, distribution, and consumption system without using direct load research data. Existing billing data may provide the amount of electricity delivered to and received from each DG customer each month, interconnection data may provide the installed on-site electricity generation capacity for each DG customer, and the average hourly output from a sample of DG or utility/community scale facility may provide a representative generation profile. The load shapes may include the load delivered to DG customers, the excess generated electricity exported back to the electricity distribution network by the DG customers, the generated electricity consumed on-site, and the load in the absence of DG facility(ies)/customer(s). The load shapes have many applications, such as determining cost-of-service, forecasting load, responding to demand, developing standards for distribution systems for serving DG customers, designing rates, and other purposes.

### FIELD

The present invention concerns systems and methods of analyzing electricity consumption by customers of an electric utility, and more particularly, embodiments that concern a system and a computer-implemented method for improving the functioning of a computer for determining load shapes for distributed generation customers in an electricity generation, distribution, and consumption system without using direct load research data for the load shape of retail customers after the installation of distributed generation at their premises.

### BACKGROUND

Distributed generation (“DG”) customers are those customers of an electric utility who generate part of their electricity needs on-site and rely on the electric utility to provide the remainder. The most common example of DG customers is residential customers with solar panels (photovoltaics (PV)) on their roofs, although other fuel sources, such as wind or water, can also be used. DG customers are therefore defined as “partial requirement” customers because they rely on electric utilities and the distribution network for only part of their needs. In most cases, the electric utility delivers electricity to DG customers and receives excess electricity from DG customers, depending on the DG customers' demand for electricity, or amount of load, and their on-site facilities' generation of electricity (production) at any given time. Such DG customers are often referred to as “net metered” customers because they are charged for the electricity they receive and credited for the electricity they contribute, and their meters and their bills reflect the net result.

In order to understand DG customers' demands on electric utilities, it is necessary to know their load on a periodic interval (e.g., sub-hourly or hourly) basis. This aggregated interval data is called a “load shape” and is derived by using the interval data for load and on-site generation described above. Knowing load shape is important for application in utility cost allocation, system planning, and forecasting. However, due to metering constraints, most electric utilities do not register periodic (hourly or sub-hourly) loads delivered to the DG customers or excess generation exported back to the distribution network by DG customers. Both of these quantities are recorded as a cumulative number on a monthly billing cycle basis. The load research that would be needed to obtain these interval load shapes is costly and may require a year or more to complete.

This background discussion is intended to provide information related to the present invention which is not necessarily prior art.

### SUMMARY

Embodiments address the above-described and other problems by providing a system and a computer-implemented method for improving the functioning of a computer for determining hourly (or other interval) load shapes for DG customers in an electricity generation, distribution, and consumption system without using directly metered hourly data or load research.

In a first embodiment of the present invention, a system is provided for determining one or more load shapes for a plurality of distributed generation customers, with each distributed generation customer having an on-site electricity generation facility. The system may broadly comprise an electronic communications element, an electronic memory element, and an electronic processing element. The electronic communications element may be configured to receive monthly delivery data for electricity delivered to and electricity received from each distributed generation customer over a billing cycle. The electronic memory element may be configured to store the monthly delivery data. The electronic processing element may be configured to perform the following actions. The monthly delivery data may be adjusted to a common time period. An individual on-site generation output may be estimated for electricity generated by each on-site electricity generation facility. The monthly delivery data may be matched with the on-site generation output for each distributed generation customer over the common time period. An individual “counterfactual load” (defined below in [0020]) may be calculated for each distributed generation customer. An aggregate counterfactual load may be calculated by summing the individual counterfactual loads for the plurality of distributed generation customers. An aggregate on-site generation output may be calculated by summing the individual on-site generation outputs for the plurality of distributed generation customers. An hourly counterfactual load may be determined by spreading the aggregate monthly counterfactual load across all hours of all days in the common time period based on a known hourly demand profile for a plurality of non-distributed generation customers. An hourly on-site generation output may be determined by spreading the aggregate monthly on-site generation output across all hours of all days in the common time period based on a known hourly on-site generation production profile for the plurality of distributed generation customers. Based on the hourly counterfactual load and the hourly on-site generation production profile, an hourly delivered load and an hourly excess output may be calculated.

In a second embodiment of the present invention, a computer-implemented method is provided for improving the functioning of a computer for determining one or more load shapes for a plurality of distributed generation customers, with each distributed generation customer having an on-site electricity generation facility. The computer-implemented method may broadly comprise the following actions. Monthly delivery data may be accessed for electricity delivered to and electricity received from each distributed generation customer over a billing cycle. The monthly delivery data may be adjusted to a common time period. An individual on-site generation output may be estimated for electricity generated by each on-site electricity generation facility. The monthly delivery data may be matched with the on-site generation output for each distributed generation customer over the common time period. An individual counterfactual load may be calculated for each distributed generation customer. An aggregate counterfactual load may be calculated by summing the individual counterfactual loads for the plurality of distributed generation customers. An aggregate on-site generation output may be calculated by summing the individual on-site generation outputs for the plurality of distributed generation customers. An hourly counterfactual load may be determined by spreading the aggregate monthly counterfactual load across all hours of all days in the common time period based on a known hourly demand profile for a plurality of non-distributed generation customers. An hourly on-site generation output may be determined by spreading the aggregate monthly on-site generation output across all hours of all days in the common time period based on a known hourly on-site generation profile for the plurality of distributed generation customers. Based on the hourly counterfactual load and the hourly on-site generation, hourly delivered load, hourly excess production, and hourly netted on-site load may be calculated.

Various implementations of the foregoing embodiments may include any one or more of the following additional features. The on-site electricity generation facility may generate electricity using a technology such as solar-based electricity generation, wind-driven electricity generation, and/or water-driven electricity generation. The monthly delivery data may be based on existing monthly billing data. The hourly delivered load and the hourly excess production may be verified by comparing the hourly delivered load and the hourly excess load to the existing monthly billing data. The hourly delivered load and the hourly excess load are expressed in units of kilowatt-hours. The individual on-site generation output may be estimated from existing installed capacity data and existing on-site generation profile data. Based on the hourly counterfactual load (defined below in [0020]) and the hourly on-site generation output, an hourly net on-site generation use, and an hourly excess output may be calculated.

The hourly delivered load and the hourly excess output may be used to do at least one of determining an actual cost of providing electricity to the plurality of distributed generation customers; forecasting a future load for the plurality of distributed generation customers; forecasting a demand response for the plurality of distributed generation customers; developing standards for distribution system design for serving distributed generation customers; and/or designing a rate for the plurality of distributed generation customers.

This summary is not intended to identify essential features of the present invention, and is not intended to be used to limit the scope of the claims. These and other aspects of the present invention are described below in greater detail.

### DRAWINGS

Embodiments of the present invention are described in detail below with reference to the attached drawing figures, wherein:

FIG. 1 is a depiction of an electricity generation, distribution, and consumption system;

FIG. 2 is a graph showing an example first load profile and an example second production profile from the system of FIG. 1; and

FIG. 3 is a flowchart of steps in a computer-implemented method for determining load shapes for a plurality of DG customers in the system of FIG. 1.

### DETAILED DESCRIPTION

The following detailed description of embodiments of the invention references the accompanying figures. The embodiments are intended to describe aspects of the invention in sufficient detail to enable those with ordinary skill in the art to practice the invention. Other embodiments may be utilized and changes may be made without departing from the scope of the claims. The following description is, therefore, not limiting. The scope of the present invention is defined only by the appended claims, along with the full scope of equivalents to which such claims are entitled.

In this description, references to “one embodiment”, “an embodiment”, or “embodiments” mean that the feature or features referred to are included in at least one embodiment of the invention. Separate references to “one embodiment”, “an embodiment”, or “embodiments” in this description do not necessarily refer to the same embodiment and are not mutually exclusive unless so stated. Specifically, a feature, structure, act, etc. described in one embodiment may also be included in other embodiments, but is not necessarily included. Thus, particular implementations of the present invention can include a variety of combinations and/or integrations of the embodiments described herein.

Broadly characterized, the present invention provides a system and method of analyzing electricity usage by customers of an electric utility. More particularly, embodiments provide a system and a computer-implemented method for improving the functioning of a computer for determining load shapes for DG customers in an electricity generation, distribution, and consumption system without using direct load research data for power delivered to the customer over a defined set of time intervals. The load shapes to be developed may include the load delivered to DG customers, the excess electricity generation exported back to the electricity distribution network by the DG customers, the electricity consumed on-site, and the load in the absence of DG customers (i.e., counterfactual or full-requirement load). The developed load shapes have multiple applications in areas such as cost-of-service, load forecasting (future load and/or past load contribution), demand response, distribution system planning and rate design (i.e., determining the actual costs of serving DG customers as part of setting appropriate rates).

Existing data specific to each DG customer may be used in place of direct load research data. For example, monthly billing data may be a source of data for the amount of electricity delivered to and received from each DG customer each month. Interconnection data may be a source of data for the installed on-site electricity generation capacity for each DG customer. An average hourly/interval output from a sample of DG or utility/community scale facility may be a source of data for a representative generation profile; modeled generation may be an additional or alternative source of this data. Using such existing and readily available data, embodiments may provide substantially instantaneous results that are within an acceptable range of error while avoiding the need for costly direct load research data collection which can require a year or more to complete.

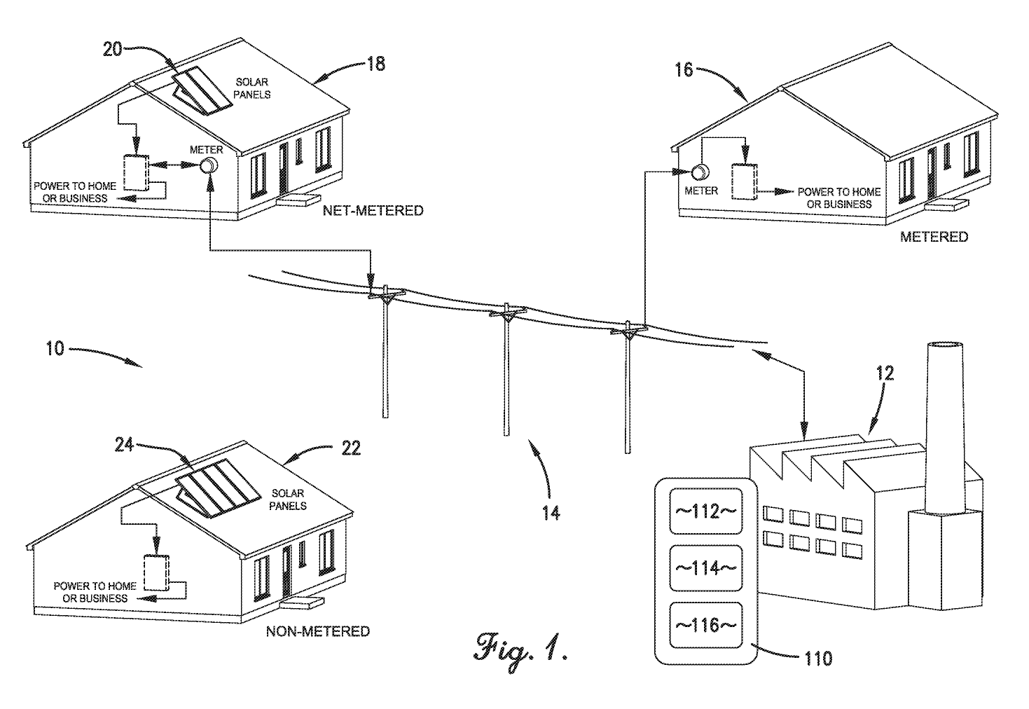

Referring to FIG. 1, an electricity generation, transmission, distribution, and consumption system 10 is shown broadly comprising an electric utility 12, an electricity distribution network 14, a plurality of non-DG customers 16, a plurality of net-metered DG customers 18 who have their own on-site electricity generation facilities 20 but are still connected to the distribution network 14, and, possibly, a plurality of non-metered DG customers 22 who have their own on-site electricity generation facilities 24 and are not connected to the distribution network 14. In some embodiments and/or for some purposes, the non-net-metered DG customers 22, if any, may be excluded from consideration. In general, each net-metered DG customer 18 may receive some of the electricity they consume from their own on-site generation facility 20, which may generate electricity using solar, wind, water, and/or substantially any other suitable technologies, and may receive the remainder of the electricity they consume from the electric utility 12. When the on-site generation facility 20 generates more electricity than the DG customer 18 needs at the time, the excess electricity may be exported via the distribution network 14 to the utility for its use in serving other customers.

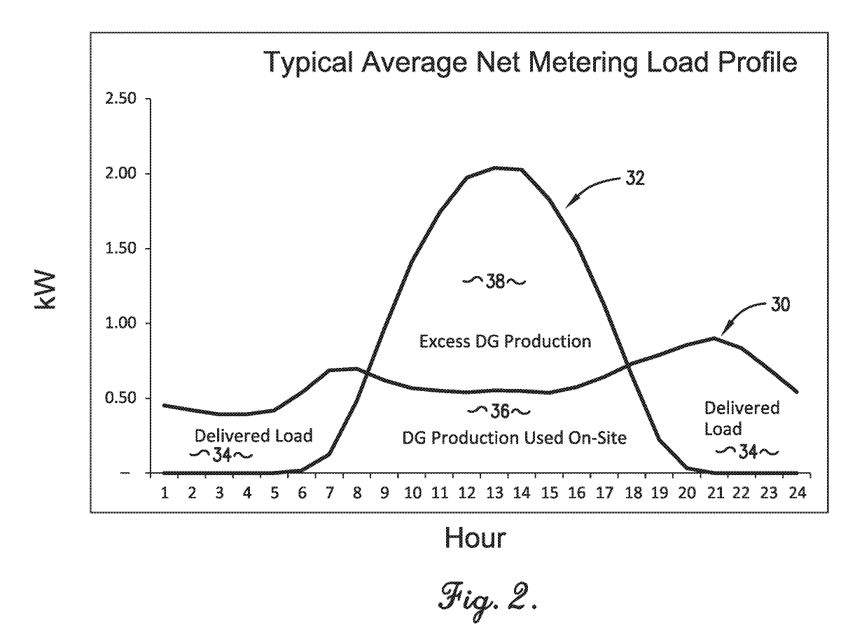

Referring to FIG. 2, a first load profile 30 and a second production profile 32 are shown. The first load profile 30 reflects the typical electricity consumption (in kWh) or load measured over hourly intervals 34 of a typical full requirements customer over a twenty-four period. The difference between non-DG customers 16 and DG customers 18 is that when the latter's on-site generation facility 20 may generate some electricity (e.g., during daylight hours for a solar-based facility), during which time the DG customer receives less or no electricity from the distribution network 14. For the DG customer 18, the first load profile 30 may be referred to as the “counterfactual” or “full requirements” load. As used herein, “counterfactual load” is defined as the amount of electric load a DG customer would impose on the delivery system if it were a full requirements customer, i.e., a customer that relies on the delivery system for 100% of its electric delivery needs.

The DG production profile 32 reflects the electricity generation by the DG customer's on-site generation facility 20. The consumed portion 36 of what is generated, which corresponds with the first load profile 32, may replace electricity otherwise received from the distribution network 14 (“netted on site”), while the excess portion 38 of what is generated, which is above the first load profile 30, may be exported via the distribution network 14 (excess output). The shape of the second load profile 32 shown in FIG. 2 may be different for non-solar-based on-site generation facilities 20.

Thus, for example, for a DG customer 18 using a solar-based on-site generation facility 20, the interaction of the two profiles 30, 32 may divide the DG customer's load into three distinct areas. The first area 34 may be mornings (before 9:00 AM) and evenings (after 6:00 PM) when the required load exceeds electricity generation by the on-site facility 18 and must be provided or at least supplemented by electricity received from the network 14. It will be understood that the illustrated pattern is only an example, and actual hourly load and production profiles will be specific to a delivery system's unique characteristics, including geographic location, orientation, ambient temperature (for solar production), customer profiles and end uses, and other factors.

The second area 36 may arise as electricity generation by the on-site facility 18 increases and all or at least some of this generation is used to satisfy the DG customer's counterfactual load. The third area 38 may arise once the electricity generation by the on-site facility 20 exceeds the required load, and all or some of the excess is exported via the distribution network 14.

For the DG customers 18, delivered load and excess generation may be measured at their meter or meters (hence the term “net-metered”). On-site generation can also be estimated by knowing the installed capacity and generation profile of the on-site electricity generation facility 18. Therefore, the DG customer's counterfactual load can be estimated using the following formula: Counterfactual Load=Delivered Load+On-Site Generation−Excess Production (Generation).

Referring again to FIG. 1, an embodiment of a computer system 110 is shown for determining load shapes for net-metered DG customers 18, in the absence of direct load research data for interval delivered loads. The computer system 110 may broadly comprise an electronic memory element 112, an electronic processing element 114, and an electronic communications element 116. The electronic memory element 112 may be configured to store relevant electronic data. The memory element 16 may include one or more forms of volatile and/or non-volatile, fixed and/or removable memory, such as read-only memory (ROM), electronic programmable read-only memory (EPROM), random access memory (RAM), erasable electronic programmable read-only memory (EEPROM), and/or other hard drives, flash memory, MicroSD cards, and others.

The electronic processing element 114 may be configured to execute a computer program which implements an embodiment of the computer-implemented method of the present invention, which may involve accessing data stored on the memory element 112 and/or engaging in communication via the electronic communications element 116.

The electronic communications element 116 may be configured to collect, access, or otherwise receive data, such as the billing data 40, the installed capacity data 42, and the on-site generation profile data 44, via an electronic communications network. The electronic communications element 116 may include one or more transceivers (e.g., WWAN, WLAN, and/or WPAN transceivers) functioning in accordance with IEEE standards, 3GPP standards, or other standards, and configured to receive and transmit data via the electronic communications network. The electronic communications network 24 may facilitate substantially any type of data communications via any standard or technology (e.g., GSM, CDMA, TDMA, WCDMA, LTE, EDGE, OFDM, GPRS, EV-DO, UWB, WiFi, IEEE 802 including Ethernet, WiMAX, and/or others). The electronic communications network 116 may also support various local area networks (LANs), personal area networks (PAN), or short-range communications protocols.

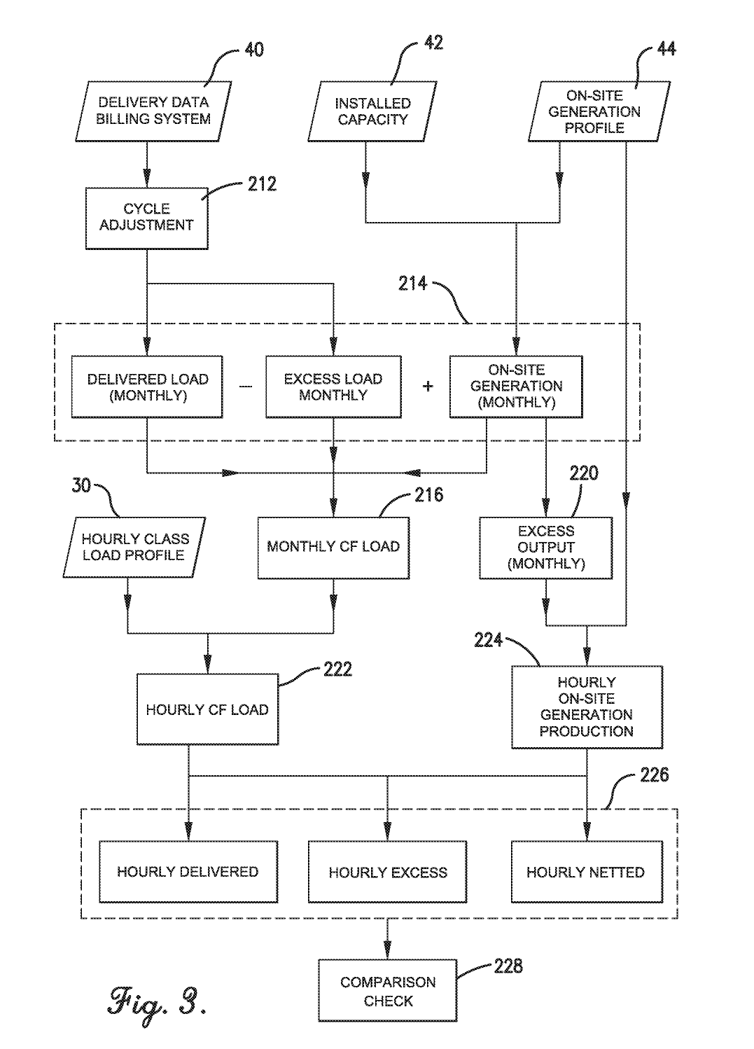

Referring to FIG. 3, the computer system 110 may function substantially as follows. Monthly delivery data may be accessed from the billing system for electricity aggregated over the month as electricity delivered to (delivered) and received from (excess output) each DG customer 18 over a monthly billing cycle; and, the collected monthly delivery data may be adjusted to a common time period, as shown in 212. For each DG customer 18, on-site monthly generation output may be estimated, and added to the monthly delivery; excess output generation output is then subtracted from this amount to derive a monthly counterfactual load for each DG customer 18 over the common time period (in accordance with the formula set forth above), as shown in 214. An aggregate monthly counterfactual load may be calculated by summing the individual counterfactual loads for the plurality of DG customers 18, as shown in 216. An aggregate monthly on-site generation output may also be calculated by summing the individual on-site generation output for the plurality of DG customers 18, as shown in 220.

An hourly counterfactual load may be determined by spreading the aggregate monthly counterfactual load across all hours of all days in the common time period based on a known hourly load profile derived from a statistically valid load research sample of interval data for a plurality of non-DG customers 18, as shown in 222. An hourly on-site generation output profile may be similarly determined by spreading the aggregate monthly on-site generation output across all hours of all days in the common time period based on a known hourly on-site generation profile for the plurality of DG customers 18, as shown in 224.

Based on the hourly counterfactual load and the hourly on-site generation, an hourly delivered load, hourly excess output, and hourly “netted on-site” may be calculated, as shown in 226. Calculating the hourly delivered load and the hourly excess output may include calculating various customer or class specific loads necessary to determine a class non-coincident peak (NCP), a sub-class NCP, a sum of customer NCPs, class coincident peak loads (CP) and other interval demand measurements used to provide data to support the purposes described herein. The hourly delivered load and the hourly excess output may be used for many purposes, such as determining an actual cost of providing electricity to the plurality of DG customers 18; forecasting a future load and/or past load contribution for the plurality of DG customers 18; forecasting a demand response for the plurality of DG customers 18; developing standards for distribution systems design for serving DG customers 18; and planning distribution system capacity requirements and designing a rate for the plurality of DG customers 18. Hourly “netted on-site” may be used to determine the timing and amount of DG production that is used by the DG facility owner for its own load purposes and which bypasses the distribution system.

The computer system 110 may include more, fewer, or alternative components and/or perform more, fewer, or alternative actions, including those discussed elsewhere herein, and particularly those discussed in the following section describing the computer-implemented method.

Referring again to FIG. 3, an embodiment of a computer-implemented method 210 is shown for improving the functioning of a computer for determining load shapes for net-metered DG customers 18, in the absence of direct load research data. The computer-implemented method 210 may be a corollary to the functionality of the computer system 110 of FIG. 1, and may be similarly implemented using the various components of the computer system 110 within the above-described system 10. Broadly, the method 210 may proceed substantially as follows. The method 210 may make use of substantially any suitable existing data, including data for individual DG customers, such as the billing data 40 from billing records, the installed capacity data 42, and on-site generation profile data 44.

Data may be collected, accessed, or otherwise received concerning monthly delivery data (in, e.g., kWh) delivered to and received from each net-metered DG customer 18, and adjusted for billing cycle, as shown in 212. The monthly delivery data may be obtained from the billing data 40. The billing periods of different customers, different subsets of customers, or the customers of different utilities may begin and end on different days, so the billing cycles may be adjusted, or normalized, to a common time period in order to facilitate comparison.

The adjusted data from step 212 may then be matched with estimated on-site generation output 44 for each DG customer 18 in the common time period, and the counterfactual load equation (set forth above in [0024]) may be used to calculate the counterfactual load for each DG customer 18, as shown in 214. These individual counterfactual loads may then be aggregated for all DG customers 18 on a monthly basis, as shown in 216. Monthly on-site generation may also be aggregated for all DG customers 18, as shown in 220.

The method may assume that, on average, the hourly counterfactual load shape of the DG customers 18 is approximately the same as non-DG customers 16 of the same class, even though the magnitude of the load may vary (i.e., that the first load profile 30 of FIG. 2 applies to both non-DG and DG customers 16,18). This assumption is based on the fact that DG customers 18 were non-DG customers prior to the installation of their on-site electricity generation facilities 20 or were new partial requirements customers using total electricity in substantially the same configurations as other full requirements customers based on the mix of end-use services commonly used by customers of the utility. Similar logic may be applied to other classes of service. Because installation of an on-site electricity generation facility 20 does not alter the premise's connected load, thermal envelope, demographics, etc., the assumption should be reasonable. With this assumption, the aggregate monthly counterfactual load obtained in 216 may be spread across all hours in proportion to the non-DG class load at the same hour-by-hour demand profile (i.e., the first load profile 30), for all days in the common time period, as shown in 222. Similarly, monthly aggregated on-site generation from step 220 may be spread across all hours in proportion to the hourly on-site generation profile (i.e., the second load profile 32 of FIG. 2), as shown in 224.

By comparing the aggregated hourly counterfactual load from step 222 with the aggregated hourly generation output from step 224, an hourly delivered load and an hourly excess output (measured in, e.g., kWh), as well as the hourly generation netted on-site, may be calculated, as shown in 226. As a check, the aggregated calculated hourly delivered load and hourly excess output may be compared with the equivalent numbers obtained from the monthly billing data 40, as shown in 228. The aggregated hourly delivered load and the hourly excess output may be used many purposes, such as determining an actual cost of providing electricity to the plurality of DG customers 18; forecasting a future load and/or past load contribution for the plurality of DG customers 18; forecasting a demand response for the plurality of DG customers 18; developing standards for distribution systems design for serving DG customers 18; and planning distribution system capacity requirements and designing a rate for the plurality of DG customers 18.

The computer-implemented method 210 may include more, fewer, or alternative actions, including those discussed elsewhere herein.

Although the invention has been described with reference to the one or more embodiments illustrated in the figures, it is understood that equivalents may be employed and substitutions made herein without departing from the scope of the invention as recited in the claims.

Having thus described one or more embodiments of the invention, what is claimed as new and desired to be protected by Letters Patent includes the following:

1. A system for determining one or more load shapes for a plurality of distributed generation customers, with each distributed generation customer having an on-site electricity generation facility, the system comprising:
an electronic communications element configured to receive monthly delivery data for electricity delivered to and electricity received from each distributed generation customer over a billing cycle;
an electronic memory element configured to store the monthly delivery data; and
an electronic processing element configured to—
adjust the monthly delivery data to a common time period,
estimate an individual on-site generation output for electricity generated by each on-site electricity generation facility,
match the monthly delivery data with the individual on-site generation output for each distributed generation customer over the common time period,
calculate an individual counterfactual load for each distributed generation customer;
calculate an aggregate counterfactual load by summing the individual counterfactual loads for the plurality of distributed generation customers,
calculate an aggregate on-site generation output by summing the individual on-site generation outputs for the plurality of distributed generation customers,
determine an hourly counterfactual load by spreading the aggregate monthly counterfactual load across all hours of all days in the common time period based on a known hourly demand profile for a plurality of non-distributed generation customers,
determine an hourly on-site generation output by spreading the aggregate monthly on-site generation output across all hours of all days in the common time period based on a known hourly on-site generation profile for the plurality of distributed generation customers, and
calculate, based on the hourly counterfactual load and the hourly on-site generation, an hourly delivered load and an hourly excess output.

2. The system of claim 1, wherein the on-site electricity generation facility generates electricity using a technology selected from the group consisting of: solar-based electricity generation, wind-driven electricity generation, water-driven electricity generation.

3. The system of claim 1, wherein the monthly delivery data is based on existing monthly billing data.

4. The system of claim 3, the electronic processing element being further configured to verify the hourly delivered load and the hourly excess output by comparing the hourly delivered load and the hourly excess output to the existing monthly billing data.

5. The system of claim 1, wherein the hourly delivered load and the hourly excess output are expressed in units of kilowatt-hours per hour or kW demand.

6. The system of claim 1, wherein the individual on-site generation output is estimated from existing installed capacity data and existing on-site generation profile data.

7. The system of claim 1, further including calculating, based on the hourly counterfactual load and the hourly on-site generation, an hourly net on-site generation use.

8. The system of claim 1, wherein the electronic processing element is further configured to use the hourly delivered load and the hourly excess output to do at least one of—
determine an actual cost of providing electricity to the plurality of distributed generation customers,
forecast a future load for the plurality of distributed generation customers,
forecast a demand response for the plurality of distributed generation customers, and
design a rate for the plurality of distributed generation customers.

9. A computer-implemented method for improving the functioning of a computer for determining one or more load shapes for a plurality of distributed generation customers, with each distributed generation customer having an on-site electricity generation facility, the computer-implemented method comprising:
accessing monthly delivery data for electricity delivered to and electricity received from each distributed generation customer over a billing cycle;
adjusting the monthly delivery data to a common time period;
estimating an individual on-site generation output for electricity generated by each on-site electricity generation facility;
matching the monthly delivery data with the individual on-site generation output for each distributed generation customer over the common time period;
calculating an individual counterfactual load for each distributed generation customer;
calculating an aggregate counterfactual load by summing the individual counterfactual loads for the plurality of distributed generation customers;
calculating an aggregate on-site generation output by summing the individual on-site generation outputs for the plurality of distributed generation customers;
determining an hourly counterfactual load by spreading the aggregate monthly counterfactual load across all hours of all days in the common time period based on a known hourly demand profile for a plurality of non-distributed generation customers;
determining an hourly on-site generation by spreading the aggregate monthly on-site generation output across all hours of all days in the common time period based on a known hourly on-site generation profile for the plurality of distributed generation customers;
calculating, based on the hourly counterfactual load and the hourly on-site generation use, an hourly delivered load and an hourly excess output.

10. The computer-implemented method of claim 9, wherein the on-site electricity generation facility generates electricity using a technology selected from the consisting of: solar-based electricity generation, wind-driven electricity generation, and water-driven electricity generation.

11. The computer-implemented method of claim 9, wherein the monthly delivery data is based on existing monthly billing data.

12. The computer-implemented method of claim 11, further including verifying the hourly delivered load and the hourly excess output by comparing the hourly delivered load and the hourly excess output to the existing monthly billing data.

13. The computer-implemented method of claim 9, wherein the hourly delivered load and the hourly excess output are expressed in units of kilowatt-hours.

14. The computer-implemented method of claim 9, wherein the individual on-site generation output is estimated from existing installed capacity data and existing on-site generation profile data.

15. The computer-implemented method of claim 9, further including calculating, based on the hourly counterfactual load and the hourly on-site generation, and hourly net on-site generation output.

16. The computer-implemented method of claim 9, further including using the hourly
delivered load and the hourly excess output to do at least one of—determining an actual cost of providing electricity to the plurality of distributed generation customers;
forecasting a future load for the plurality of distributed generation customers;
forecasting a demand response for the plurality of distributed generation customers;
developing standards for distribution system design for serving distributed generation customers; and
designing a rate for the plurality of distributed generation customers.

17. A computer-implemented method for improving the functioning of a computer for determining one or more load shapes for a plurality of distributed generation customers, with each distributed generation customer having an on-site electricity generation facility, the computer-implemented method comprising:
collecting monthly delivery data for electricity delivered to and electricity received from each distributed generation customer over a billing cycle, wherein the monthly delivery data is collected from existing monthly billing data;
adjusting the monthly delivery data to a common time period;
estimating an individual on-site generation output for electricity generated by each on-site electricity generation facility, wherein the individual on-site generation output is estimated from existing installed capacity data and existing on-site generation profile data;
matching the monthly delivery data with the individual on-site generation output for each distributed generation customer over the common time period;
calculating an individual counterfactual load for each distributed generation customer;
calculating an aggregate counterfactual load by summing the individual counterfactual loads for the plurality of distributed generation customers;
calculating an aggregate on-site generation output by summing the individual on-site generation outputs for the plurality of distributed generation customers;
determining an hourly counterfactual load by spreading the aggregate monthly counterfactual load across all hours of all days in the common time period based on a known hourly demand profile for a plurality of non-distributed generation customers;
determining an hourly on-site generation use by spreading the aggregate monthly on-site generation output across all hours of all days in the common time period based on a known hourly on-site generation profile for the plurality of distributed generation customers;
calculating, based on the hourly counterfactual load and the hourly on-site generation use, an hourly delivered load and an hourly excess output; and
using the hourly delivered load and the hourly excess output to do at least one of—
determining an actual cost of providing electricity to the plurality of distributed generation customers,
forecasting a future load for the plurality of distributed generation customers,
forecasting a demand response for the plurality of distributed generation customers,
developing standards for distribution system design for serving distributed generation customers, and
designing a rate for the plurality of distributed generation customers.

18. The computer-implemented method of claim 17, wherein the on-site electricity generation facility generates electricity using a technology selected from the consisting of: solar-based electricity generation, wind-driven electricity generation, and water-driven electricity generation.

19. The computer-implemented method of claim 17, further including verifying the hourly delivered load and the hourly excess output by comparing the hourly delivered load and the hourly excess output to the existing monthly billing data.

20. The computer-implemented method of claim 17, further including calculating, based on the hourly counterfactual load and the hourly on-site generation, an hourly net on-site generation use.
